(19) United States
(12) Patent Application Publication
(10) Pub. No.: US 2017/0323960 A1
(43) Pub. Date: Nov. 9, 2017

(54) EPITAXIAL WAFER, SEMICONDUCTOR DEVICE, METHOD FOR PRODUCING EPITAXIAL WAFER, AND METHOD FOR PRODUCING SEMICONDUCTOR DEVICE

(71) Applicants: SANKEN ELECTRIC CO., LTD., Niiza-shi, Saitama (JP); SHIN-ETSU HANDOTAI CO., LTD., Tokyo (JP)

(72) Inventors: Ken SATO, Miyoshi-machi (JP); Hiroshi SHIKAUCHI, Niiza-shi (JP); Hirokazu GOTO, Minato-ku (JP); Masaru SHINOMIYA, Annaka-shi (JP); Keitaro TSUCHIYA, Takasaki-shi (JP); Kazunori HAGIMOTO, Takasaki-shi (JP)

(73) Assignees: SANKEN ELECTRIC CO., LTD., Niiza-shi, Saitama (JP); SHIN-ETSU HANDOTAI CO., LTD., Tokyo (JP)

(21) Appl. No.: 15/525,153

(22) PCT Filed: Nov. 6, 2015
(86) PCT No.: PCT/JP2015/005562

§ 371 Date: May 8, 2017

(30) Foreign Application Priority Data
Nov. 25, 2014 (JP) 2014-237683

(51) Int. Cl. H01L 29/778; H01L 21/02; C30B 29/68; C30B 25/18; C30B 29/40; C30B 25/22; H01L 29/20

(52) U.S. Cl. CPC H01L 29/778; H01L 29/2003; H01L 21/0254; H01L 21/02458; H01L 21/02381; C30B 25/183; C30B 29/406; C30B 29/403; C30B 25/22; C30B 29/68

(57) ABSTRACT

An epitaxial wafer including: a silicon-based substrate; a first buffer layer on the substrate and including a first multilayer structure buffer region composed of AlₓGa₁₋ₓN layers and Al_{y}Ga_{1-y}N layers (x>y) alternately disposed and a first insertion layer composed of an Al_{z}Ga_{1-z}N layer (x>z) and is thicker than the Al_{y}Ga_{1-y}N layer, the first regions and insertion layers alternately disposed; a second buffer layer on the first and including a second multilayer structure buffer region composed of Al_{α}Ga_{1-α}N layers and Al_{β}Ga_{1-β}N layers (α>β) alternately disposed and a second insertion layer composed of an Al_{γ}Ga_{1-γ}N layer (α>γ) and is thicker than the Al_{β}Ga_{1-β}N layer, the second regions and insertion layers alternately disposed; and a channel layer on the second buffer layer and thicker than the second insertion layer. The average Al composition in the second buffer layer is higher than that in the first.

### TECHNICAL FIELD

The present invention relates to epitaxial wafers, semiconductor devices, methods for producing the epitaxial wafer, and methods for producing the semiconductor device.

### BACKGROUND ART

A nitride semiconductor layer is generally formed on an inexpensive silicon substrate or sapphire substrate. However, the lattice constants of these substrates greatly differ from the lattice constant of the nitride semiconductor layer and the thermal coefficients of expansion of these substrates also differ from the thermal coefficient of expansion of the nitride semiconductor layer. Thus, considerable strain energy is generated in the nitride semiconductor layer formed on the substrate by epitaxial growth. As a result, the nitride semiconductor layer tends to suffer from the occurrence of a crack or a reduction in crystal quality.

In order to solve the problem, a method of disposing a buffer layer composed of stacked nitride semiconductor layers between a silicon substrate and an active layer composed of a nitride semiconductor is proposed (see, for example, Patent Document 1).

A semiconductor wafer having the buffer layer of Patent Document 1 is depicted in FIG. 6.

In a semiconductor wafer 1 of FIG. 6, a buffer layer 3 is provided between a silicon substrate 2 and an active layer 4 (which is composed of an electron transit layer 4a and an electron supply layer 4b), and the buffer layer 3 has a first multilayer structure buffer region 5, a second single-layer structure buffer region 8 which is composed of GaN and is provided on the first multilayer structure buffer region 5, and a second multilayer structure buffer region 5′ provided on the second single-layer structure buffer region 8.

Furthermore, the first multilayer structure buffer region 5 and the second multilayer structure buffer region 5′ each have a multilayer structure in which sub-multilayer structure buffer regions 6 and first single-layer structure buffer regions 7, each being composed of GaN and thinner than the second single-layer structure buffer region 8, are repeatedly stacked.

Moreover, the sub-multilayer structure buffer region 6 has a multilayer structure in which first layers composed of AlN and second layers composed of GaN are repeatedly stacked.

In Patent Document 1, a method of reducing warpage of a semiconductor wafer by forming the first layer by using a nitride semiconductor containing aluminum in a first proportion and making the proportion of aluminum in the second layer, the first single-layer structure buffer region 7, and the second single-layer structure buffer region 8 smaller than the first proportion, that is, by reducing the aluminum composition in an upper portion (the second multilayer structure buffer region 5′ and the second single-layer structure buffer region 8) of the buffer layer 3 is, disclosed.

### CITATION LIST

### Patent Literature

Patent Document 1: Japanese Unexamined Patent publication (Kokai) No. 2008-205117

### DISCLOSURE OF INVENTION

### Problem to be Solved by the Invention

As described above, in order to improve the characteristics of a nitride semiconductor layer formed on a silicon substrate or a sapphire substrate, a buffer layer has been provided and the configuration of the buffer layer has been optimized.

However, the present inventors have found out that the configuration of the conventional buffer layer has some room for improvement in terms of warpage of a wafer and the occurrence of an internal crack.

The present invention has been made in view of the problem, and an object thereof is to provide an epitaxial wafer that can reduce warpage of a wafer and suppress the occurrence of an internal crack.

### Means for Solving Problem

In order to attain the object, the present invention provides an epitaxial wafer including: a silicon-based substrate; a first buffer layer that is disposed on the silicon-based substrate and includes a first multilayer structure buffer region composed of AlₓGa₁₋ₓN layers and Al_{y}Ga_{1-y}N layers (x>y) which are alternately disposed and a first insertion layer which is composed of an Al_{z}Ga_{1-z}N layer (x>z) and is thicker than the Al_{y}Ga_{1-y}N layer, the first multilayer structure buffer regions and the first insertion layers being alternately disposed; a second buffer layer that is disposed on the first buffer layer and includes a second multilayer structure buffer region composed of Al_{α}Ga_{1-α}N layers and Al_{β}Ga_{1-β}N layers (α>β) which are alternately disposed and a second insertion layer which is composed of an Al_{γ}Ga_{1-γ}N layer (α>γ) and is thicker than the Al_{β}Ga_{1-β}N layer, the second multilayer structure buffer regions and the second insertion layers being alternately disposed; and a channel layer that is disposed on the second buffer layer and is thicker than the second insertion layer, wherein the average Al composition in the second buffer layer is higher than the average Al composition in the first buffer layer.

With the epitaxial wafer configured as described above, by making higher the average Al composition in an upper portion of a buffer layer and the average Al composition in a lower portion (a region below the upper portion of the buffer layer) of the buffer layer, it is possible to reduce warpage of a wafer and suppress the occurrence of an internal crack while reducing a peripheral crack. This makes it possible to provide a semiconductor device with excellent electrical characteristics, such as breakdown voltage, and high reliability when the semiconductor device is fabricated by using this epitaxial wafer.

At this time, it is preferable that the second insertion layer is thinner than the first insertion layer.

With such a configuration, it is possible to increase the average Al composition in the upper portion of the buffer layer effectively and thereby reduce warpage of a wafer effectively and suppress the occurrence of an internal crack effectively.

At this time, it is preferable that the number of repetitions of the Al_{α}Ga_{1-α}N layers and the Al_{β}Ga_{1-β}N layers of the second multilayer structure buffer region is larger than the number of repetitions of the AlₓGa₁₋ₓN layers and the Al_{y}Ga_{1-y}N layers of the first multilayer structure buffer region.

With such a configuration, it is possible to make higher the average Al composition in the upper portion of the buffer layer and thereby reduce warpage of a wafer more effectively and suppress the occurrence of an internal crack more effectively.

At this time, it is preferable that each of the Al_{β}Ga_{1-β}N layers of the second multilayer structure buffer region is thinner than each of the Al_{y}Ga_{1-y}N layers of the first multilayer structure buffer region.

With such a configuration, it is possible to make higher the average Al composition in the upper portion of the buffer layer and thereby reduce warpage of a wafer more effectively and suppress the occurrence of an internal crack more effectively.

At this time, it is preferable that each of the Al_{α}Ga_{1-α}N layers of the second multilayer structure buffer region is thicker than each of the AlₓGa₁₋ₓN layers of the first multilayer structure buffer region.

Also with such a configuration, it is possible to make higher the average Al composition in the upper portion of the buffer layer and thereby reduce warpage of a wafer more effectively and suppress the occurrence of an internal crack more effectively.

At this time, it is preferable that, in the Al_{α}Ga_{1-α}N layers of the second multilayer structure buffer region and the AlₓGa₁₋ₓN layers of the first multilayer structure buffer region, x<α is satisfied.

Also with such a configuration, it is possible to make higher the average Al composition in the upper portion of the buffer layer and thereby reduce warpage of a wafer more effectively and suppress the occurrence of an internal crack more effectively.

At this time, it is preferable that, in the Al_{β}Ga_{1-β}N layers of the second multilayer structure buffer region and the Al_{y}Ga_{1-y}N layers of the first multilayer structure buffer region, y<β is satisfied.

Also with such a configuration, it is possible to make higher the average Al composition in the upper portion of the buffer layer and thereby reduce warpage of a wafer more effectively and suppress the occurrence of an internal crack more effectively.

Moreover, the present invention provides a semiconductor device including: the above-described epitaxial wafer; a barrier layer that is composed of a gallium nitride-based semiconductor and is disposed on the epitaxial wafer; and a first electrode, a second electrode, and a control electrode which are disposed on the barrier layer.

With the semiconductor device configured as described above, it is possible to increase the average Al composition in the upper portion of the buffer layer and suppress the occurrence of an internal crack by reducing warpage of a wafer, which makes it possible to provide a semiconductor device with excellent electrical characteristics, such as breakdown voltage, and high reliability.

Furthermore, the present invention provides a method for producing an epitaxial wafer, including: preparing a silicon-based substrate; forming, on the silicon-based substrate by epitaxial growth, a first buffer layer including a first multilayer structure buffer region composed of AlₓGa₁₋ₓN layers and Al_{y}Ga_{1-y}N layers (x>y) which are alternately disposed and a first insertion layer which is composed of an Al_{z}Ga_{1-z}N layer (x>z) and is thicker than the Al_{y}Ga_{1-y}N layer, the first multilayer structure buffer regions and the first insertion layers being alternately disposed; forming, on the first buffer layer by epitaxial growth, a second buffer layer including a second multilayer structure buffer region composed of Al_{α}Ga_{1-α}N layers and Al_{β}Ga_{1-β}N layers (α>β) which are alternately disposed and a second insertion layer which is composed of an Al_{γ}Ga_{1-γ}N layer (α>γ) and is thicker than the Al_{β}Ga_{1-β}N layer, the second multilayer structure buffer regions and the second insertion layers being alternately disposed; and forming a channel layer that is thicker than the second insertion layer on the second buffer layer by epitaxial growth, wherein the average Al composition in the second buffer layer is made higher than the average Al composition in the first buffer layer.

By using such a method for producing an epitaxial wafer, it is possible to increase the average Al composition in the upper portion of the buffer layer and suppress the occurrence of an internal crack while reducing a peripheral crack by reducing warpage of a wafer, which makes it possible to produce an epitaxial wafer with which a semiconductor device with excellent electrical characteristics, such as breakdown voltage, and high reliability is fabricated.

At this time, it is preferable that, by making the second insertion layer thinner than the first insertion layer, the average Al composition in the second buffer layer is made higher than the average Al composition in the first buffer layer.

By using such a method for producing an epitaxial wafer, it is possible to increase the average Al composition in the upper portion of the buffer layer effectively.

Moreover, the present invention provides a method for producing a semiconductor device, including: forming, on the epitaxial wafer produced by the method, a barrier layer composed of a gallium nitride-based semiconductor by epitaxial growth; and forming a first electrode, a second electrode, and a control electrode on the barrier layer.

By using such a method for producing a semiconductor device, it is possible to increase the average Al composition in the upper portion of the buffer layer and suppress the occurrence of an internal crack by reducing warpage of a wafer, which makes it possible to produce a semiconductor device with excellent electrical characteristics, such as breakdown voltage, and high reliability.

### Effect of the Invention

As described above, with the epitaxial wafer of the present invention, it is possible to increase the average Al composition in the upper portion of the buffer layer and thereby suppress the occurrence of an internal crack by reducing warpage of a wafer, which makes it possible to provide a semiconductor device with excellent electrical characteristics, such as breakdown voltage, and high reliability when the semiconductor device is fabricated by using this epitaxial wafer.

### BRIEF DESCRIPTION OF DRAWINGS

FIG. 1 is a schematic sectional view depicting an example of an embodiment of an epitaxial wafer of the present invention;

FIG. 2 is a schematic sectional view depicting an example of an embodiment of a semiconductor device of the present invention;

FIG. 3 is a process sectional view depicting an example of an embodiment of a method for producing the epitaxial wafer of the present invention;

FIG. 4 is a process sectional view depicting an example of an embodiment of a method for producing the semiconductor device of the present invention;

FIG. 5 is a diagram depicting the definition of the amount of warpage of a wafer;

FIG. 6 is a schematic sectional view of a semiconductor wafer having a conventional buffer layer;

FIG. 7 is a schematic sectional view depicting an example of an internal crack in the structure of FIG. 6; and

FIG. 8 is a diagram depicting a Nomarski image (a differential interference microscope image) of the internal crack in the structure of FIG. 6.

### BEST MODE FOR CARRYING OUT THE INVENTION

Hereinafter, the present invention will be described in detail as an example of an embodiment with reference to the drawings, but the present invention is not limited to this example.

As described earlier, in order to improve the characteristics of a nitride semiconductor layer formed on a silicon substrate or a sapphire substrate, a buffer layer has been provided and the configuration of the buffer layer has been optimized, but, in the conventional buffer layer, there is some room for improvement in terms of warpage of a wafer and the occurrence of an internal crack.

Thus, the present inventors made an intensive study of an epitaxial wafer that can reduce warpage of a wafer and suppress the occurrence of an internal crack.

As a result, the present inventors have found out that, by adopting a configuration in which the average Al composition in a second buffer layer located in an upper portion of a buffer layer is higher than the average Al composition in a first buffer layer located in a lower portion of the buffer layer, it is possible to increase the average Al composition in the upper portion of the buffer layer, which makes it possible to reduce warpage of a wafer and suppress the occurrence of an internal crack, thereby bringing the present invention to completion.

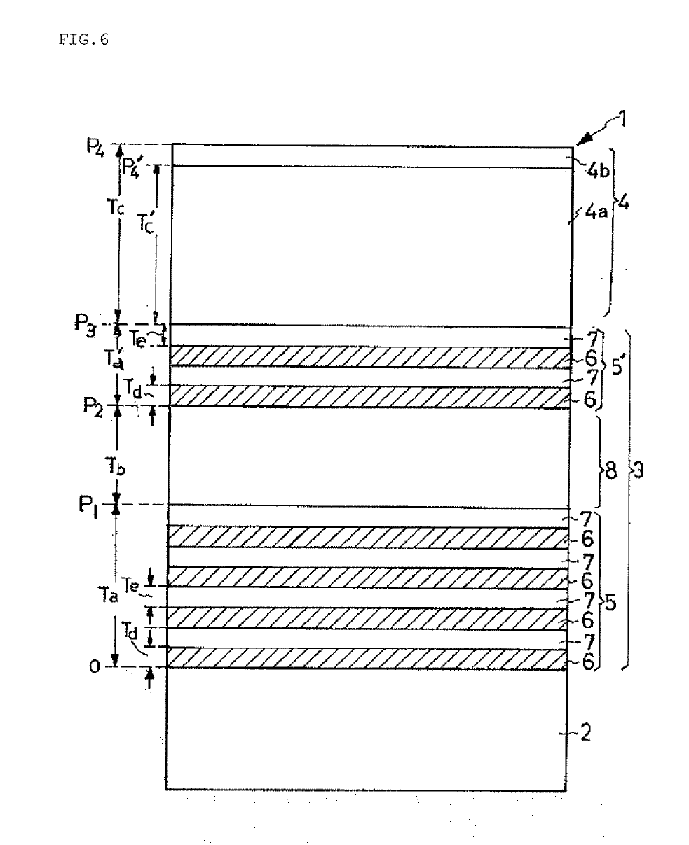

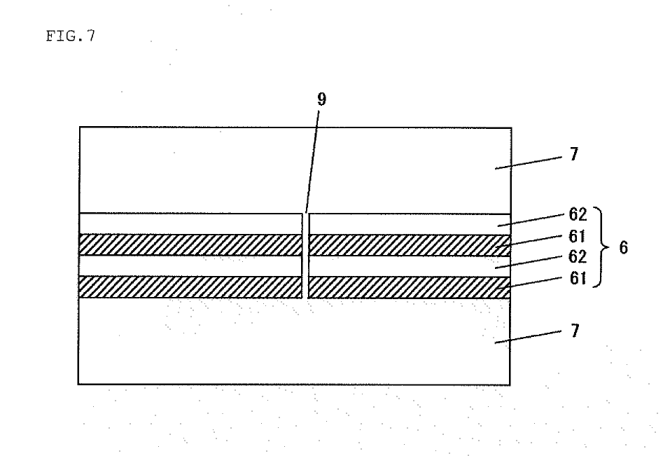

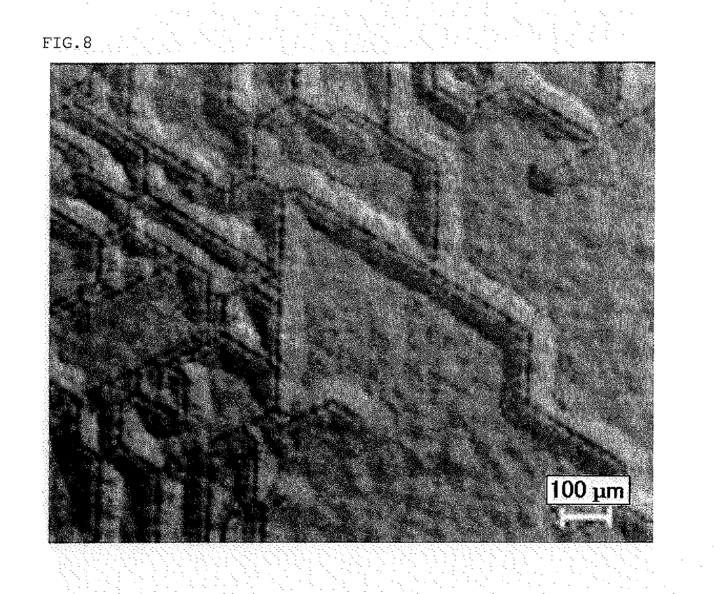

Here, the internal crack is a phenomenon in which a crack appears during epitaxial growth under the influence of a membrane stress; an example of the internal crack in the structure of FIG. 6 is depicted in FIG. 7. FIG. 7 depicts a state in which an internal crack 9 has appeared in the sub-multilayer structure buffer region 6 (that is composed of first layers 61 and second layers 62 which are alternately stacked) of the first multilayer structure buffer region 5 of FIG. 6. Moreover, a Nomarski image (a differential interference microscope image) of the internal crack in the structure of FIG. 6 is depicted in FIG. 8. Since the inside portion of the internal crack that appeared by the occurrence of such an internal crack is filled in during the subsequent epitaxial growth, the surface of the epitaxial layer after the epitaxial growth is flat. However, in the case of FIG. 7, the inside of the internal crack 9 is filled with the material of the first single-layer structure buffer region 7, which affects electrical characteristics, such as breakdown voltage, and reliability.

A mechanism that suppresses the occurrence of such an internal crack will be described below.

In a structure in which GaN layers (or AlGaN layers with lower Al composition) I and AlN layers (or AlGaN layers with higher Al composition) II are alternately stacked, an internal crack appears as a result of the AlN layers (or the AlGaN layers with higher Al composition) II being cracked by being pulled by the GaN layers (or the AlGaN layers with lower Al composition) I. Thus, in order to suppress the occurrence of an internal crack, it is necessary to reduce a tensile stress which is applied to the AlN layers (or the AlGaN layers with higher Al composition) II. In a buffer structure in which the GaN layers (or the AlGaN layers with lower Al composition) I and the AlN layers (or the AlGaN layers with higher Al composition) II are alternately stacked, since the GaN layers (or the AlGaN layers with lower Al composition) I exhibit gradual lattice relaxation with distance from a silicon substrate, by increasing the average Al composition in, in particular, an upper portion of the buffer structure, the internal crack suppression effect is presumed to be obtained by increasing distortion of the GaN layers (or the AlGaN layers with lower Al composition) T and decreasing distortion of the AlN layers (or the AlGaN layers with higher Al composition) II in the upper portion of the buffer structure as compared to the conventional example.

Moreover, a mechanism that reduces warpage of a wafer will be described below.

With an increase in the average Al composition in an upper portion of a buffer layer, a strong compressive stress is applied also to a GaN layer (that is, a channel layer) which is formed thereon. This presumably causes a considerable deformation toward a negative side (that is, warpage of a wafer on a negative side) during epitaxial growth and reduces warpage of the wafer (warpage of the wafer on a positive side) which is observed when the wafer is returned to room temperature after the epitaxial growth. Incidentally, as a result of a reduction in the warpage of the wafer, a crack which appears in the periphery of the wafer (hereinafter referred to as a peripheral crack) is also suppressed.

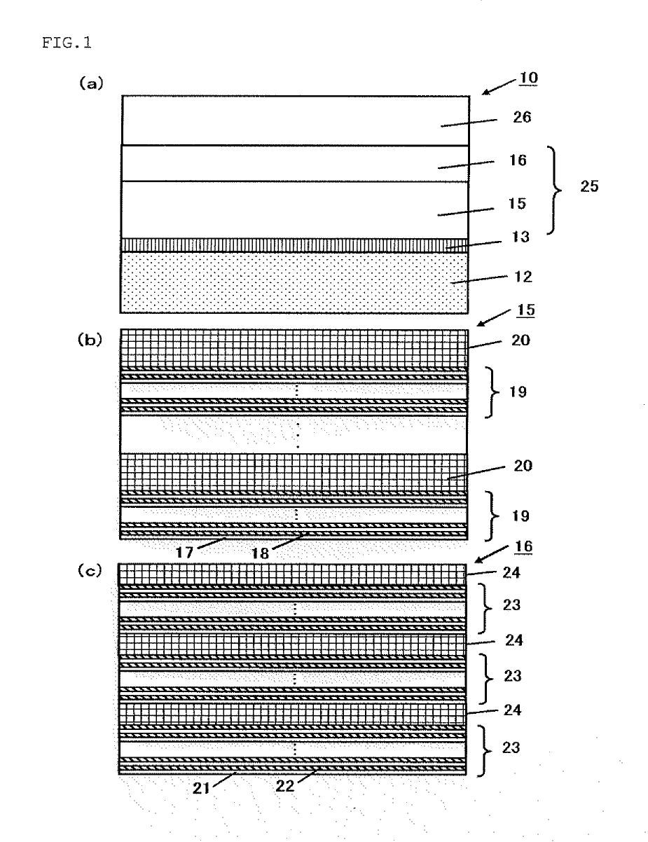

First, with reference to FIG. 1, an example of an embodiment of an epitaxial wafer of the present invention will be described.

An epitaxial wafer 10 of the present invention depicted in FIG. 1(a) includes a silicon-based substrate 12, a buffer layer 25 provided on the silicon-based substrate 12, and a channel layer 26 provided on the buffer layer 25.

Here, the silicon-based substrate 12 is a substrate composed of Si or SiC, for example.

The buffer layer 25 has a first buffer layer 15 and a second buffer layer 16 provided on the first buffer layer 15.

As depicted in FIG. 1(b), the first buffer layer 15 is composed of first multilayer structure buffer regions 19 and first insertion layers 20 which are alternately stacked. The first multilayer structure buffer region 19 is composed of AlₓGa₁₋ₓN layers 17 and Al_{y}Ga_{1-y}N layers (x>y) 18 which are alternately stacked, and the first insertion layer 20 is composed of an Al_{z}Ga_{1-z}N layer (x>z) and is thicker than the Al_{y}Ga_{1-y}N layer (x>y) 18.

Here, the layer 17 can be formed as an AlN layer (that is, x=1) or an AlGaN layer, the Al_{y}Ga_{1-y}N layer 18 can be formed as a GaN layer (that is, y=0), and the first insertion layer 20 can be formed as a GaN layer (that is, z=0).

As depicted in FIG. 1(c), the second buffer layer 16 is composed of second multilayer structure buffer regions 23 and second insertion layers 24 which are alternately stacked. The second multilayer structure buffer region 23 is composed of Al_{α}Ga_{1-α}N layers 21 and Al_{β}Ga_{1-β}N layers (α>β) 22 which are alternately stacked, and the second insertion layer 24 is composed of an Al_{γ}Ga_{1-γ}N layer (α>γ) and is thicker than the Al_{β}Ga_{1-β}N layer 22. Furthermore, the second insertion layer 24 is configured so as to be thinner than the first insertion layer 20.

Here, the Al_{α}Ga_{1-α}N layer 21 can be formed as an AlN layer (that is, α=1) or an AlGaN layer, the Al_{β}Ga_{1-β}N layer 22 can be formed as a GaN layer (that is, β=0), and the second insertion layer 24 can be formed as a GaN layer (that is, γ=0).

Examples of possible combinations of the AlₓGa₁₋ₓN layer 17 and the Al_{y}Ga_{1-y}N layer 18 of the first multilayer structure buffer region 19 and the Al_{α}Ga_{1-α}N layer 21 and the Al_{β}Ga_{1-β}N layer 22 of the second multilayer structure buffer region 23 are depicted in Table 1.

TABLE 1

| | Second multilayer | | First multilayer | |
|---|---|---|---|---|
| | structure buffer | | structure buffer | |
| | region 23 | | region 19 | |
| | Al_{α}Ga_{1-α}N | Al_{β}Ga_{1-β}N | AlₓGa₁₋ₓN | Al_{y}Ga_{1-y}N |
| | layer 21 | layer 22 | layer 17 | layer 18 |
| Combination | AlN | Al_{0.3}Ga_{0.7}N | AlN | Al_{0.1}Ga_{0.9}N |
| Example | | | | |
| 1 (x = α, | | | | |
| y < β) | | | | |
| Combination | Al_{0.8}Ga_{0.2}N | Al_{0.3}Ga_{0.7}N | Al_{0.6}Ga_{0.4}N | Al_{0.1}Ga_{0.9}N |
| Example | | | | |
| 2 (x < α, | | | | |
| y < β) | | | | |
| Combination | Al_{0.8}Ga_{0.2}N | Al_{0.3}Ga_{0.7}N | Al_{0.6}Ga_{0.4}N | Al_{0.5}Ga_{0.5}N |
| Example | | | | |
| 3 (x < α, | | | | |
| y > β) | | | | |

The channel layer 26 is composed of a GaN layer, an AlGaN layer, or an InGaN layer which is thicker than the second insertion layer 24, a composite layer including an InGaN layer on a thick GaN layer, or the like. Incidentally, between the silicon-based substrate 12 and the buffer layer 25, an AlN initial layer 13 may be provided (see FIG. 1(a)).

As described above, by adopting a configuration in which the average Al composition in the second buffer layer 16 is higher than the average Al composition in the first buffer layer 15, it is possible to increase the average Al composition in the upper portion of the buffer layer 25 and thereby suppress the occurrence of an internal crack while reducing a peripheral crack by reducing warpage of a wafer. This makes it possible to provide a semiconductor device with excellent electrical characteristics, such as breakdown voltage, and high reliability when the semiconductor device is fabricated by using this epitaxial wafer.

In the epitaxial wafer 10 of FIG. 1, it is preferable that the second insertion layer 24 is thinner than the first insertion layer 20.

With such a configuration, it is possible to make the average Al composition in the upper portion of the buffer layer 25 effectively higher than the average Al composition in a lower portion of the buffer layer 25 below the upper portion of the buffer layer 25, which makes it possible to reduce warpage of a wafer effectively and suppress the occurrence of an internal crack effectively.

In the epitaxial wafer 10 of FIG. 1, it is preferable that the number of repetitions of the Al_{α}Ga_{1-α}N layers 21 and the Al_{β}Ga_{1-β}N layers 22 of the second multilayer structure buffer region 23 is larger than the number of repetitions of the Al_{z}Ga₁₋ₓN layers 17 and the Al_{y}Ga_{1-y}N layers 18 of the first multilayer structure buffer region 19.

With such a configuration, it is possible to make the average Al composition in the upper portion of the buffer layer 25 more effectively higher than the average Al composition in the lower portion of the buffer layer 25 below the upper portion of the buffer layer 25, which makes it possible to reduce warpage of a wafer more effectively and suppress the occurrence of an internal crack more effectively.

In the epitaxial wafer 10 of FIG. 1, it is preferable that the Al_{β}Ga_{1-β}N layer 22 of the second multilayer structure buffer region 23 is thinner than the Al_{y}Ga_{1-y}N layer 18 of the first multilayer structure buffer region 19.

With such a configuration, it is possible to make the average Al composition in the upper portion of the buffer layer 25 more effectively higher than the average Al composition in the lower portion of the buffer layer 25 below the upper portion of the buffer layer 25, which makes it possible to reduce warpage of a wafer more effectively and suppress the occurrence of an internal crack more effectively.

Furthermore, in the epitaxial wafer 10 of FIG. 1, it is preferable that the Al_{α}Ga_{1-α}N layer 21 of the second multilayer structure buffer region 23 is thicker than the AlₓGa₁₋ₓN layer 17 of the first multilayer structure buffer region 19.

Moreover, when a comparison between the Al_{α}Ga_{1-α}N layer 21 of the second multilayer structure buffer region 23 and the AlₓGa₁₋ₓN layer 17 of the first multilayer structure buffer region 19 is made, it is preferable that x<α. For example, the Al_{α}Ga_{1-α}N layer 21 may be formed as an Al_{0.8}Ga_{0.2}N layer and the AlₓGa₁₋ₓN layer 17 may be formed as an Al_{0.6}Ga_{0.4}N layer.

In addition, when a comparison between the Al_{β}Ga_{1-β}N layer 22 of the second multilayer structure buffer region 23 and the Al_{y}Ga_{1-y}N layer 18 of the first multilayer structure buffer region 19 is made, it is preferable that y<β. For example, the Al_{β}Ga_{1-β}N layer 22 may be formed as an Al_{0.3}Ga_{0.7}N layer and the Al_{y}Ga_{1-y}N layer 18 may be formed as an Al_{0.1}Ga_{0.9}N layer.

Also with such a configuration, it is possible to make the average Al composition in the upper portion of the buffer layer 25 more effectively higher than the average Al composition in the lower portion of the buffer layer 25 below the upper portion of the buffer layer 25, which makes it possible to reduce warpage of a wafer more effectively and suppress the occurrence of an internal crack more effectively.

As a method for increasing the average Al composition in the upper portion of the buffer layer 25, a plurality of methods may be performed at the same time, whereby it is possible to increase the average Al composition in the upper portion more effectively.

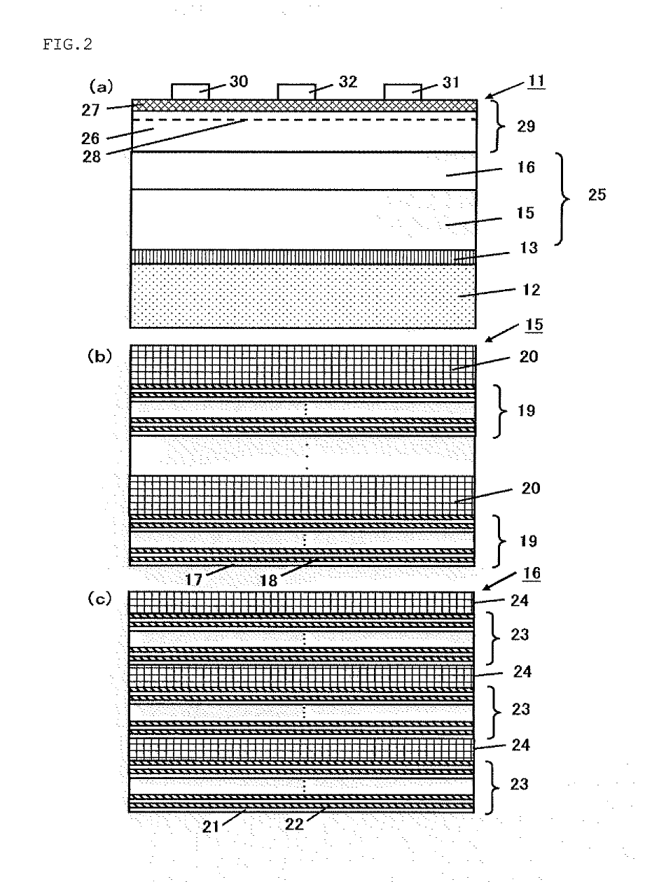

Next, with reference to FIG. 2, an example of an embodiment of a semiconductor device of the present invention will be described.

A semiconductor device 11 of the present invention depicted in FIG. 2(a) is obtained by providing a barrier layer 27 composed of a gallium nitride-based semiconductor (for example, AlGaN) on the epitaxial wafer 10 described above by using FIG. 1 and providing, on the barrier layer 27, a first electrode (a source electrode) 30, a second electrode (a drain electrode) 31, and a control electrode 32. The semiconductor device 11 is, for example, a high-electron-mobility transistor (HEMT).

The channel layer 26 and the barrier layer 27 form an active layer 29.

The first electrode 30 and the second electrode 31 are disposed such that an electric current flows into the second electrode 31 from the first electrode 30 via a two-dimensional electron gas 28 formed in the channel layer 26. The electric current flowing between the first electrode 30 and the second electrode 31 can be controlled by a potential which is applied to the control electrode 32.

With such a semiconductor device having the above configuration, by making the average Al composition in the upper portion of the buffer layer 25 higher than the average Al composition in the lower portion of the buffer layer 25 below the upper portion of the buffer layer 25, it is possible to suppress the occurrence of an internal crack while reducing a peripheral crack by reducing warpage of a wafer, and a device which is fabricated by using this wafer can be provided as a semiconductor device with excellent electrical characteristics, such as breakdown voltage, and high reliability.

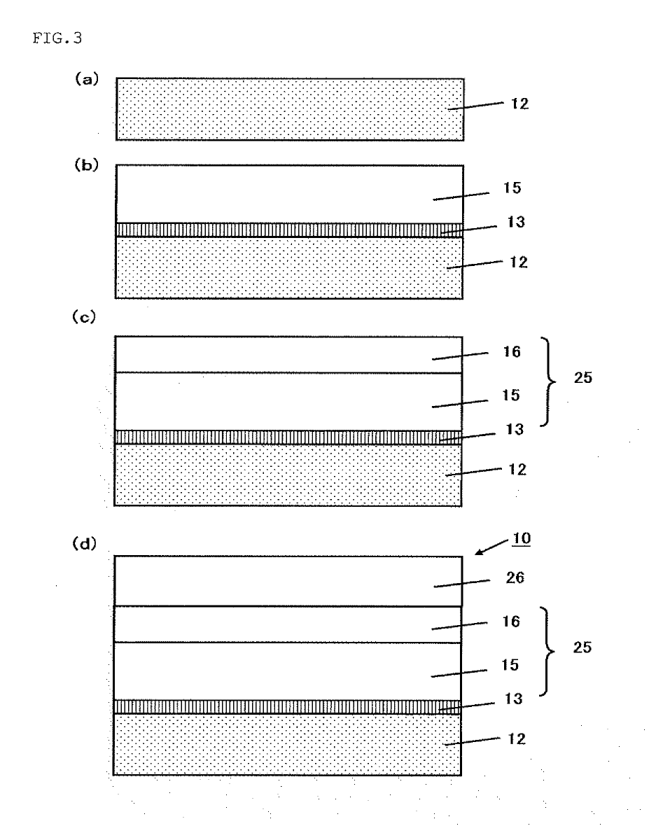

Next, with reference to FIG. 3, an example of an embodiment of a method for producing an epitaxial wafer of the present invention will be described.

First, a silicon-based substrate 12 is prepared (see FIG. 3(a)).

Specifically, as the silicon-based substrate 12, a silicon substrate or a SiC substrate is prepared. The silicon substrate or the SiC substrate is generally used as a substrate on which a nitride semiconductor layer is grown.

Next, on the silicon-based substrate 12, a first buffer layer 15 is formed by epitaxial growth (see to FIG. 3(b)).

Specifically, on the silicon-based substrate 12, the first buffer layer 15 constituting a buffer layer 25 is formed by MOVPE method (metal-organic vapor phase epitaxy method). As depicted in FIG. 1(b), the first buffer layer 15 is composed of first multilayer structure buffer regions 19 and first insertion layers 20 which are alternately stacked. The first multilayer structure buffer region 19 is composed of AlₓGa₁₋ₓN layers 17 and Al_{y}Ga_{1-y}N layers (x>y) 18 which are alternately stacked, and the first insertion layer 20 is composed of an Al_{z}Ga_{1-z}N layer (x>z) and is thicker than the Al_{y}Ga_{1-y}N layer (x>y) 18.

Here, the AlₓGa₁₋ₓN layer 17 can be formed as an AlN layer (that is, x=1), the Al_{y}Ga_{1-y}N (x>y) layer 18 can be formed as a GaN layer (that is, y=0), and the first insertion layer 20 can be formed as a GaN layer (that is, z=0).

Incidentally, before the first buffer layer 15 is formed, an AlN initial layer 13 may be formed.

Next, on the first buffer layer 15, a second buffer layer 16 is formed by epitaxial growth (see FIG. 3(c)).

Specifically, on the first buffer layer 15, the second buffer layer 16 constituting the buffer layer 25 is formed by MOVPE method. As depicted in FIG. 1(c), the second buffer layer 16 is composed of second multilayer structure buffer regions 23 and second insertion layers 24 which are alternately stacked. The second multilayer structure buffer region 23 is composed of Al_{α}Ga_{1-α}N layers 21 and Al_{β}Ga_{1-β}N layers (α>β) 22 which are alternately stacked, and the second insertion layer 24 is composed of an Al_{γ}Ga_{1-γ}N layer (α>γ) and is thicker than the Al_{β}Ga_{1-β}N layer 22. In the formation of the second buffer layer 16, the second buffer layer 16 is formed such that the average Al composition in the second buffer layer 16 is higher than the average Al composition in the first buffer layer 15.

Here, the Al_{α}Ga_{1-α}N layer 21 can be formed as an AlN layer (that is, α=1), the Al_{β}Ga_{1-β}N layer 22 can be formed as a GaN layer (that is, β=0), and the second insertion layer 24 can be formed as a GaN layer (that is, γ=0).

Next, on the second buffer layer 16, a channel layer 26 is formed by epitaxial growth (see FIG. 3(d)).

Specifically, on the second buffer layer 16, the channel layer 26 which is thicker than the second insertion layer 24 is formed by MOVPE method. The film thickness of the channel layer 26 is 1000 to 4000 nm, for example.

In this way, the epitaxial wafer 10 of FIG. 1 can be produced.

As described above, by making the average Al composition in the second buffer layer 16 higher than the average Al composition in the first buffer layer 15, it is possible to increase the average Al composition in the upper portion of the buffer layer 25 and thereby suppress the occurrence of an internal crack while reducing a peripheral crack by reducing warpage of a wafer. As a result, it is possible to produce an epitaxial wafer with which a semiconductor device with excellent electrical characteristics, such as breakdown voltage, and high reliability is fabricated.

In the above-described method for producing an epitaxial wafer, it is preferable that the average Al composition in the second buffer layer 16 is made higher than the average Al composition in the first buffer layer 15 by making the second insertion layer 24 thinner than the first insertion layer 20.

By using such a method for producing an epitaxial wafer, it is possible to make the average Al composition in the upper portion of the buffer layer 25 more effectively higher than the average Al composition in the lower portion of the buffer layer 25 below the upper portion thereof.

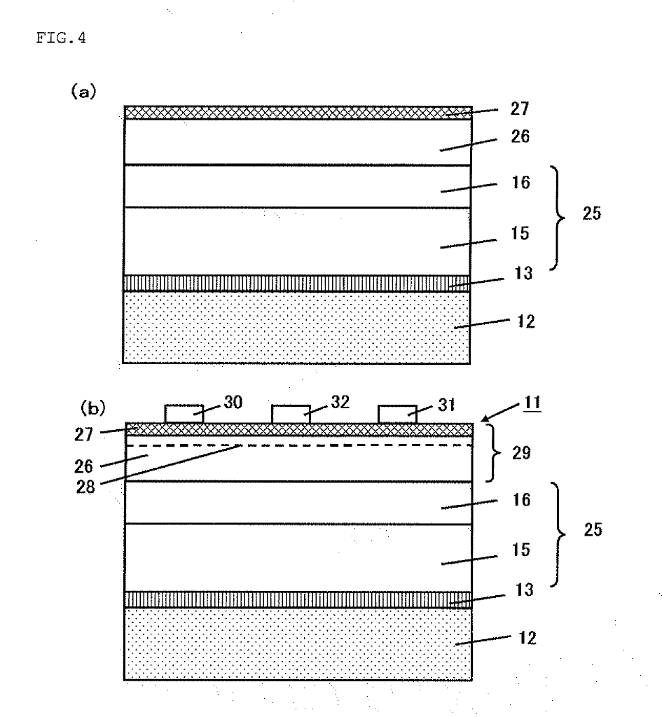

Next, with reference to FIG. 4, an example of an embodiment of a method for producing a semiconductor device of the present invention will be described.

First, on the epitaxial wafer 10 (see FIG. 3(d)) fabricated by using the production method described by using FIG. 3, a barrier layer 27 composed of a gallium nitride-based semiconductor is formed by epitaxial growth (see FIG. 4(a)).

Specifically, on the channel layer 26, the barrier layer 27 composed of AlGaN is formed by MOVPE method. The film thickness of the barrier layer 27 is 10 to 50 nm, for example.

Next, on the barrier layer 27, a first electrode (a source electrode) 30, a second electrode (a drain electrode) 31, and a control electrode 32 are formed (see FIG. 4(b)).

The first electrode (the source electrode) 30 and the second electrode (the drain electrode) 31 each can be formed as a Ti/Al stacked layer, for example, and the control electrode 32 can be formed as a stacked layer of a lower film composed of a metal oxide such as SiO or SiN and an upper film composed of a metal such as Ni, Au, Mo, or Pt.

In this way, the semiconductor device 11 of FIG. 2 can be produced.

By using such a method for producing a semiconductor device, it is possible to make the average Al composition in the upper portion of the buffer layer 25 higher than the average Al composition below the upper portion of the buffer layer 25 and thereby suppress the occurrence of an internal crack while reducing a peripheral crack by reducing warpage of a wafer. This makes it possible to produce a semiconductor device with excellent electrical characteristics, such as breakdown voltage, and high reliability.

### EXAMPLES

Hereinafter, the present invention will be described more specifically with Example and Comparative Example, but the Present invention is not limited thereto.

### Example

By using the production method described by using FIG. 3, the epitaxial wafer 10 of FIG. 1 was fabricated. However, the AlₓGa₁₋ₓN layer 17 was formed as an AlN layer, the Al_{y}Ga_{1-y}N (x>y) layer 18 was formed as a GaN layer, and the first insertion layer 20 was formed as a GaN layer. Moreover, the Al_{α}Ga_{1-α}N layer 21 was formed as an AlN layer, the Al_{β}Ga_{1-β}N layer 22 was formed as a GaN layer, and the second insertion layer 24 was formed as a GaN layer. Furthermore, the number of repetitions of layers in the first multilayer structure buffer region 19 and the number of repetitions of layers in the second multilayer structure buffer region 23 were set at 8 pairs, and the number of repetitions of layers in the second multilayer structure buffer region 23 and the number of repetitions of layers in the second insertion layer 24 were set at 3 pairs.

In addition, the first insertion layer (the GaN layer) 20 was set at 200 nm, and the second insertion layer (the GaN layer) 24 was set at 160 nm.

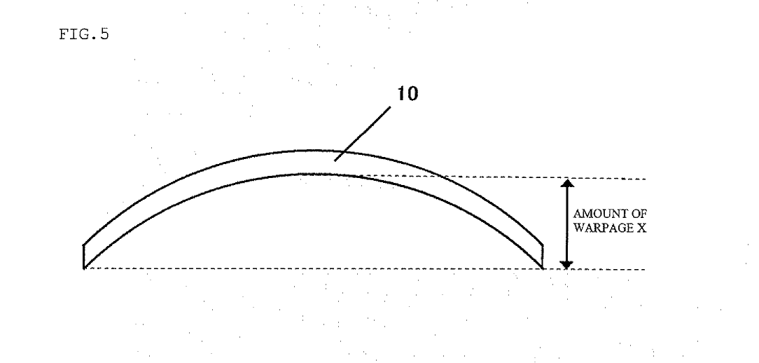

The amount of warpage of the wafer, the peripheral crack length, and the presence or absence of an internal crack of the fabricated epitaxial wafer 10 were examined. Incidentally, the amount of warpage of the wafer was measured based on the definition depicted in FIG. 5. The results are shown in Table 2.

TABLE 2

| | The amount of | | |
|---|---|---|---|
| | warpage of the | Peripheral | |
| | wafer | crack length | |
| | [μm] | [mm] | Internal crack |
| Example | 60 | 14 | None |
| Comparative | 100 | 20 | An internal |
| Example | | | crack has |
| | | | appeared. |

### Comparative Example

The epitaxial wafer 10 was fabricated in a manner similar to Example. However, the film thickness of the second insertion layer (the GaN layer) 24 was set at 200 nm.

The amount of warpage of the wafer, the peripheral crack length, and the presence or absence of an internal crack of the fabricated epitaxial wafer 10 were examined in a manner similar to Example. The results are shown in Table 2.

Table 2 reveals that, as compared to Comparative Example, in Example, the amount of warpage of the wafer is reduced, the peripheral crack length is reduced, and the occurrence of an internal crack is suppressed.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

For example, in the above-described embodiment, between the buffer layer 25 and the channel layer 26, a thick GaN layer such as a breakdown voltage layer may be provided.

1-11. (canceled)

12. An epitaxial wafer comprising:
a silicon-based substrate;
a first buffer layer that is disposed on the silicon-based substrate and includes a first multilayer structure buffer region composed of AlₓGa₁₋ₓN layers and Al_{y}Ga_{1-y}N layers (x>y) which are alternately disposed and a first insertion layer which is composed of an Al_{z}Ga_{1-z}N layer (x>z) and is thicker than the Al_{y}Ga_{1-y}N layer, the second insertion layer being thinner than the first insertion layer, the first multilayer structure buffer regions and the first insertion layers being alternately disposed;
a second buffer layer that is disposed on the first buffer layer and includes a second multilayer structure buffer region composed of Al_{α}Ga_{1-α}N layers and Al_{β}Ga_{1-β}N layers (α>β) which are alternately disposed and a second insertion layer which is composed of an Al_{γ}Ga_{1-γ}N layer (α>γ) and is thicker than the Al_{β}Ga_{1-β}N layer, the second multilayer structure buffer regions and the second insertion layers being alternately disposed; and
a channel layer that is disposed on the second buffer layer and is thicker than the second insertion layer,
wherein
an average Al composition in the second buffer layer is higher than an average Al composition in the first buffer layer.

13. The epitaxial wafer according to claim 12, wherein
a number of repetitions of the Al_{α}Ga_{1-α}N layers and the Al_{β}Ga_{1-β}N layers of the second multilayer structure buffer region is larger than a number of repetitions of the AlₓGa₁₋ₓN layers and the Al_{y}Ga_{1-y}N layers of the first multilayer structure buffer region.

14. The epitaxial wafer according to claim 12, wherein
each of the Al_{β}Ga_{1-β}N layers of the second multilayer structure buffer region is thinner than each of the Al_{y}Ga_{1-y}N layers of the first multilayer structure buffer region.

15. The epitaxial wafer according to claim 12, wherein
each of the Al_{α}Ga_{1-α}N layers of the second multilayer structure buffer region is thicker than each of the AlₓGa₁₋ₓN layers of the first multilayer structure buffer region.

16. The epitaxial wafer according to claim 12, wherein
in the Al_{α}Ga_{1-α}N layers of the second multilayer structure buffer region and the AlₓGa₁₋ₓN layers of the first multilayer structure buffer region, x<α is satisfied.

17. The epitaxial wafer according to claim 13, wherein
in the Al_{α}Ga_{1-α}N layers of the second multilayer structure buffer region and the AlₓGa₁₋ₓN layers of the first multilayer structure buffer region, x<α is satisfied.

18. The epitaxial wafer according to claim 14, wherein
in the Al_{α}Ga_{1-α}N layers of the second multilayer structure buffer region and the AlₓGa₁₋ₓN layers of the first multilayer structure buffer region, x<α is satisfied.

19. The epitaxial wafer according to claim 15, wherein
in the Al_{α}Ga_{1-α}N layers of the second multilayer structure buffer region and the AlₓGa₁₋ₓN layers of the first multilayer structure buffer region, x<α is satisfied.

20. The epitaxial wafer according to claim 12, wherein
in the Al_{β}Ga_{1-β}N layers of the second multilayer structure buffer region and the Al_{y}Ga_{1-y}N layers of the first multilayer structure buffer region, y<β is satisfied.

21. A semiconductor device comprising:
the epitaxial wafer according to claim 12;
a barrier layer that is composed of a gallium nitride-based semiconductor and is disposed on the epitaxial wafer; and
a first electrode, a second electrode, and a control electrode which are disposed on the barrier layer.

22. A semiconductor device comprising:
the epitaxial wafer according to claim 13;
a barrier layer that is composed of a gallium nitride-based semiconductor and is disposed on the epitaxial wafer; and
a first electrode, a second electrode, and a control electrode which are disposed on the barrier layer.

23. A semiconductor device comprising:
the epitaxial wafer according to claim 14;
a barrier layer that is composed of a gallium nitride-based semiconductor and is disposed on the epitaxial wafer; and
a first electrode, a second electrode, and a control electrode which are disposed on the barrier layer.

24. A semiconductor device comprising:
the epitaxial wafer according to claim 15;
a barrier layer that is composed of a gallium nitride-based semiconductor and is disposed on the epitaxial wafer; and
a first electrode, a second electrode, and a control electrode which are disposed on the barrier layer.

25. A semiconductor device comprising:
the epitaxial wafer according to claim 16;
a barrier layer that is composed of a gallium nitride-based semiconductor and is disposed on the epitaxial wafer; and
a first electrode, a second electrode, and a control electrode which are disposed on the barrier layer.

26. A semiconductor device comprising:
the epitaxial wafer according to claim 17;
a barrier layer that is composed of a gallium nitride-based semiconductor and is disposed on the epitaxial wafer; and
a first electrode, a second electrode, and a control electrode which are disposed on the barrier layer.

27. A semiconductor device comprising:
the epitaxial wafer according to claim 18;
a barrier layer that is composed of a gallium nitride-based semiconductor and is disposed on the epitaxial wafer; and
a first electrode, a second electrode, and a control electrode which are disposed on the barrier layer.

28. A semiconductor device comprising:
the epitaxial wafer according to claim 19;
a barrier layer that is composed of a gallium nitride-based semiconductor and is disposed on the epitaxial wafer; and
a first electrode, a second electrode, and a control electrode which are disposed on the barrier layer.

29. A semiconductor device comprising:
the epitaxial wafer according to claim 20;
a barrier layer that is composed of a gallium nitride-based semiconductor and is disposed on the epitaxial wafer; and
a first electrode, a second electrode, and a control electrode which are disposed on the barrier layer.

30. A method for producing an epitaxial wafer, comprising:
preparing a silicon-based substrate;
forming, on the silicon-based substrate by epitaxial growth, a first buffer layer including a first multilayer structure buffer region composed of AlₓGa₁₋ₓN layers and Al_{y}Ga_{1-y} N layers (x>y) which are alternately disposed and a first insertion layer which is composed of an Al_{z}Ga_{1-z}N layer (x>z) and is thicker than the Al_{y}Ga_{1-y}N layer, the first multilayer structure buffer regions and the first insertion layers being alternately disposed;
forming, on the first buffer layer by epitaxial growth, a second buffer layer including a second multilayer structure buffer region composed of Al_{α}Ga_{1-α}N layers and Al_{β}Ga_{1-β}N layers (α>β) which are alternately disposed and a second insertion layer which is composed of an Al_{γ}Ga_{1-γ}N layer (α>γ) and is thicker than the Al_{β}Ga_{1-β}N layer, the second multilayer structure buffer regions and the second insertion layers being alternately disposed; and
forming a channel layer that is thicker than the second insertion layer on the second buffer layer by epitaxial growth,
wherein
an average Al composition in the second buffer layer is made higher than an average Al composition in the first buffer layer, and
wherein
the second insertion layer is made thinner than the first insertion layer.

31. A method for producing a semiconductor device, comprising:
forming, on the epitaxial wafer produced by the method according to claim 30, a barrier layer composed of a gallium nitride-based semiconductor by epitaxial growth; and
forming a first electrode, a second electrode, and a control electrode on the barrier layer.
